(19) United States
(12) Patent Application Publication
(10) Pub. No.: US 2022/0384234 A1
(43) Pub. Date: Dec. 1, 2022

(54) METHOD FOR TRANSFERRING ELECTRONIC ELEMENTS

(71) Applicant: ASTI GLOBAL INC., TAIWAN, Taichung City (TW)

(72) Inventor: Ying-Chieh Chen, Taichung City (TW)

(73) Assignee: ASTI GLOBAL INC., TAIWAN, Taichung City (TW)

(21) Appl. No.: 17/671,553

(22) Filed: Feb. 14, 2022

(30) Foreign Application Priority Data
May 25, 2021 (TW) 110118806

(51) Int. Cl. H01L 21/68; H01L 21/683

(52) U.S. Cl. CPC H01L 21/682; H01L 21/6835; H01L 2221/68322; H01L 33/005

(57) ABSTRACT

A method for transferring electronic elements includes providing a transfer substrate including a transfer surface, and disposing electronic elements on the transfer surface; providing a target substrate including a target surface, and disposing the target substrate opposite to the transfer substrate, so that the transfer surface faces toward the target surface; providing a guiding mask including at least one guiding structure, and disposing the guiding mask between the transfer substrate and the target substrate; and releasing at least one of the electronic elements disposed on the transfer surface, and guiding the at least one of the electronic elements by the at least one guiding structure, so as to transfer the at least one of the electronic elements to the target surface of the target substrate. The present invention can achieve a high transferring yield rate even under a condition of low equipment accuracy and low equipment stability.

### BACKGROUND OF THE INVENTION

### 1. Field of the Invention

The present invention relates to a method for transferring electronic elements, and more particularly, to a method for transferring electronic elements, which can achieve a high transferring yield rate even under a condition of low equipment accuracy and low equipment stability.

### 2. Description of the Prior Art

With trend of micronized electronic elements, transferring of the electronic elements between different substrates requires equipment with high accuracy and high stability. When requirements of the accuracy and the stability cannot be satisfied, the two corresponding substrates may not be aligned and/or parallel to each other completely, so that the transferred electronic elements may be displaced, disoriented or even flipped, which causes failure of transferring the electronic elements to target positions correctly. In order to prevent the aforementioned situation, a conventional solution is to improve the equipment to satisfy the requirement of the accuracy and the stability, which causes higher cost and lower efficiency. Therefore, it becomes an important topic to achieve a high transferring yield rate even under a condition of low equipment accuracy and low equipment stability.

### SUMMARY OF THE INVENTION

It is an objective of the present invention to provide a method for transferring electronic elements, which can achieve a high transferring yield rate even under a condition of low equipment accuracy and low equipment stability for solving the aforementioned problem.

In order to achieve the aforementioned objective, the present invention discloses a method for transferring electronic elements. The method includes providing a transfer substrate comprising a transfer surface, and disposing a plurality of electronic elements on the transfer surface; providing a target substrate comprising a target surface, and disposing the target substrate opposite to the transfer substrate, so that the transfer surface faces toward the target surface; providing a guiding mask comprising at least one guiding structure, and disposing the guiding mask between the transfer substrate and the target substrate; and releasing at least one of the plurality of electronic elements disposed on the transfer surface, and guiding the at least one of the plurality of electronic elements by the at least one guiding structure to transfer the at least one of the plurality of electronic elements to the target surface of the target substrate.

According to an embodiment of the present invention, the method further includes contacting two sides of the guiding mask with the transfer substrate and the target substrate respectively.

According to an embodiment of the present invention, a thickness of the guiding mask is greater than a thickness of each of the plurality of electronic elements, so that each of the plurality of electronic elements is prevented from contacting with the target substrate when the guiding mask contacts with the transfer substrate and the target substrate.

According to an embodiment of the present invention, the method further includes releasing the at least one of the plurality of electronic elements disposed on the transfer surface by applying at least one laser beam.

According to an embodiment of the present invention, the method further includes disposing an adhesive layer on the transfer surface, so as to dispose the plurality of electronic elements on the transfer surface by the adhesive layer.

According to an embodiment of the present invention, the method further includes disposing an adhesive layer on the target surface, so as to adhere the at least one released electronic element to the target surface by the adhesive layer.

According to an embodiment of the present invention, a bore diameter of the at least one guiding structure is greater than a width of a corresponding one of the plurality of electronic elements.

In summary, in the present invention, the released electronic element can be guided by the guiding structure of the guiding mask, so as to transfer the released electronic element to the target surface of the target substrate correctly and accurately. Therefore, the present invention does not necessarily require equipment with high accuracy and high stability. In other words, the present invention can achieve a high transferring yield rate even under a condition of low equipment accuracy and low equipment stability. Furthermore, the guiding mask of the present invention can be reused, which reduces manufacturing cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a method for transferring electronic elements according to an embodiment of the present invention.

FIG. 2 to FIG. 7 are diagrams illustrating different stages in the method for transferring the electronic elements according to the embodiment of the present invention.

FIG. 8 and FIG. 9 are diagrams illustrating a stage of providing a guiding mask in a method for transferring electronic elements according to different embodiments of the present invention.

FIG. 10 is a diagram of the guiding mask according to the embodiment of the present invention.

### DETAILED DESCRIPTION

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “left”, “right”, “front”, “back”, etc., is used with reference to the orientation of the Figure(s) being described. The components of the present invention can be positioned in a number of different orientations. As such, the directional terminology is used for purposes of illustration and is in no way limiting. Accordingly, the drawings and descriptions will be regarded as illustrative in nature and not as restrictive.

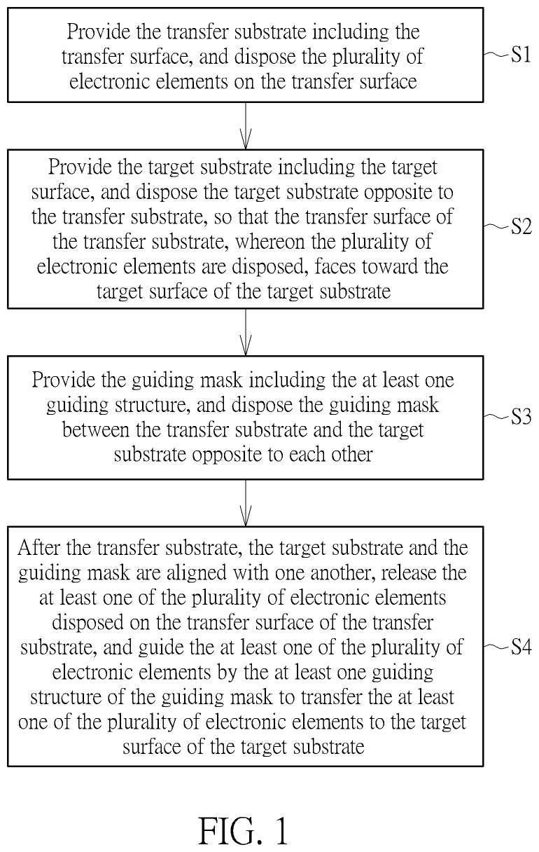

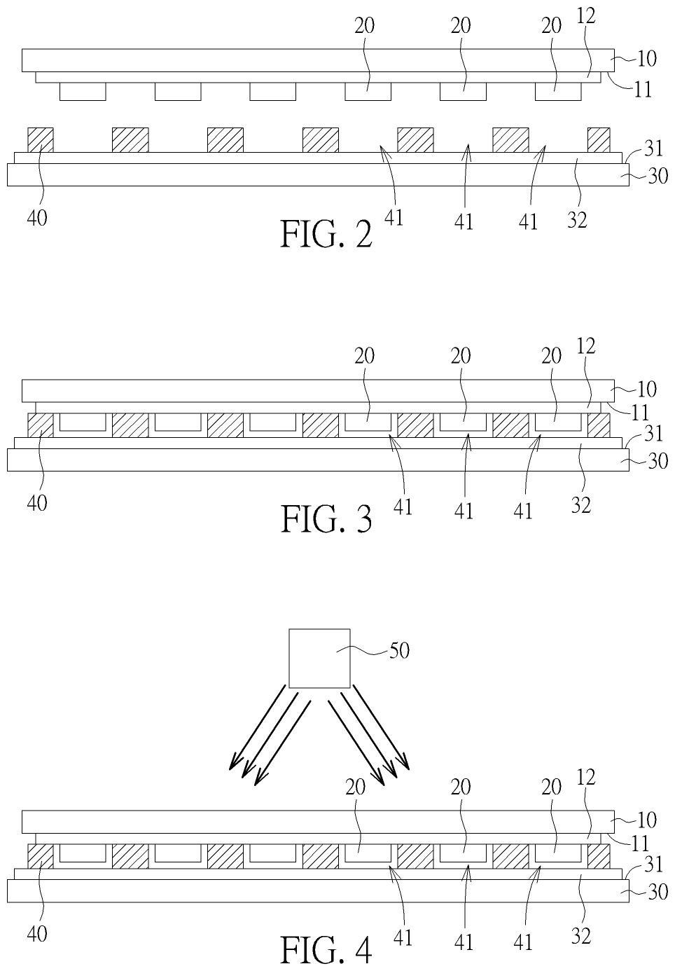

Please refer to FIG. 1 to FIG. 7. FIG. 1 is a flow chart of a method for transferring electronic elements according to an embodiment of the present invention. FIG. 2 to FIG. 7 are diagrams illustrating different stages in the method for transferring the electronic elements according to the embodiment of the present invention. As shown in FIG. 1, the method for transferring the electronic elements includes the following steps:
step S1: Provide a transfer substrate 10 including a transfer surface 11, and dispose a plurality of electronic elements 20 on the transfer surface 11;
step S2: Provide a target substrate 30 including a target surface 31, and dispose the target substrate 30 opposite to the transfer substrate 10, so that the transfer surface 11 of the transfer substrate 10, whereon the plurality of electronic elements 20 are disposed, faces toward the target surface 31 of the target substrate 30;
step S3: Provide a guiding mask 40 including at least one guiding structure 41, and dispose the guiding mask 40 between the transfer substrate 10 and the target substrate 30 opposite to each other; and
step S4: After the transfer substrate 10, the target substrate 30 and the guiding mask 40 are aligned with one another, release at least one of the plurality of electronic elements 20 disposed on the transfer surface 11 of the transfer substrate 10, and guide the at least one of the plurality of electronic elements 20 by the at least one guiding structure 41 of the guiding mask 40 to transfer the at least one of the plurality of electronic elements 20 to the target surface 31 of the target substrate 30.

Detailed description for the aforementioned steps is provided as follows. In step S1, as shown in FIG. 2, the transfer substrate 10 is provided with the transfer surface 11, and the plurality of plurality of electronic elements 20 are disposed on the transfer surface 11. Each electronic element 20 can be a micro light emitting diode (micro LED) or a mini light emitting diode (mini LED). There can be an adhesive layer 12 disposed on the transfer surface 11, so that the electronic elements 20 can be disposed on the transfer surface 11 of the transfer substrate 10 by the adhesive layer 12. However, the present invention is not limited thereto. For example, in another embodiment, the electronic element can be any other electronic component and can be disposed on the transfer surface by any other mechanism, such as magnetic adhesion, electrostatic adhesion or negative pressure adhesion.

In step S2, as shown in FIG. 2, the target substrate 30 is provided with the target surface 31, and the target substrate 30 and the transfer substrate 10 are disposed opposite to each other, so that the transfer surface 11 of the transfer substrate 10, whereon the plurality of electronic elements 20 are disposed, faces toward the target surface 31 of the target substrate 30. There can be an adhesive layer 32 disposed on the target surface 31 of the target substrate 30 to adhere the released electronic element 20. However, the present invention is not limited thereto. For example, in another embodiment, the electronic element can be fixed onto the target substrate by any other mechanism, such as magnetic adhesion, electrostatic adhesion or negative pressure adhesion.

In step S3, as shown in FIG. 2 and FIG. 3, the guiding mask 40 is provided with the at least one guiding structure 41, and the guiding mask 40 is disposed between the transfer substrate 10 and the target substrate 30 opposite to each other. In step S4, as shown in FIG. 3 to FIG. 5, after the transfer substrate 10, the target substrate 30 and the guiding mask 40 are aligned with one another, the at least one of the plurality of electronic elements 20 disposed on the transfer surface 11 of the transfer substrate 10 can be released, so that the released at least one of the plurality of electronic elements 20 can be guided by the at least one guiding structure 41 of the guiding mask 40, so as to accurately transfer the released at least one of the plurality of electronic elements 20 to at least one target position on the target surface 31 of the target substrate 30 respectively. In this embodiment, the transfer substrate 10 and the target substrate 30 can be respectively disposed on two movable platforms, and, as shown in FIG. 2 and FIG. 3, when the guiding mask 40 is provided, the guiding mask 40 can be aligned with the target substrate 30 and adhered to the target substrate 30 by the adhesive layer 32. Afterwards, by a relative movement of the two platforms, the transfer substrate 10, the guiding mask 40 and the target substrate 30 can be aligned with one another.

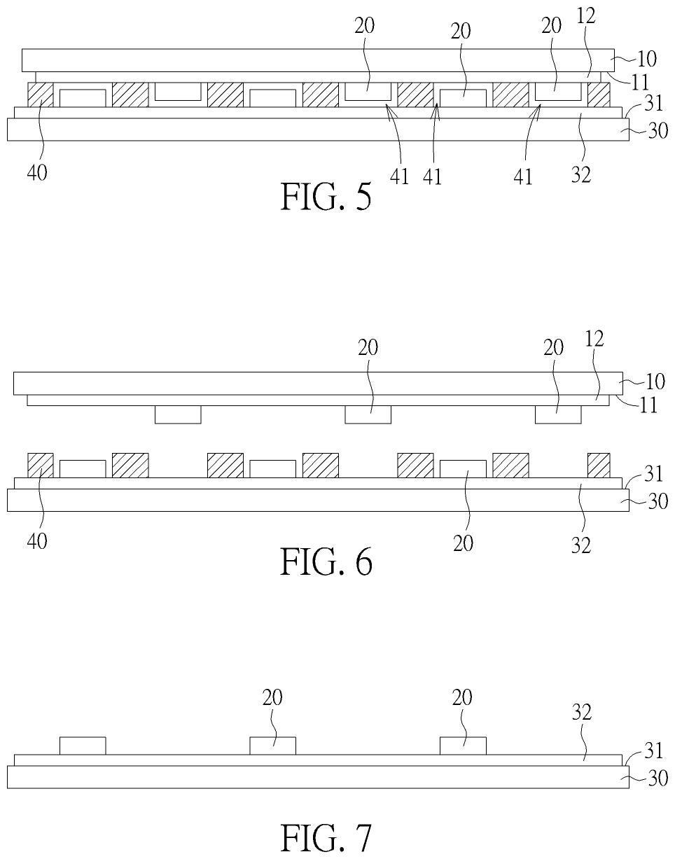

However, the present invention is not limited to this embodiment. For example, please refer to FIG. 8 and FIG. 9. FIG. 8 and FIG. 9 are diagrams illustrating a stage of providing the guiding mask 40 in a method for transferring electronic elements according to different embodiments of the present invention. In an embodiment of FIG. 8, the guiding mask 40 can be disposed on the transfer surface 11 of the transfer substrate 10 by the adhesive layer 12. In an embodiment of FIG. 9, the guiding mask 40, the transfer substrate 10 and the target substrate 30 can be respectively disposed on three different movable platforms, so that the transfer substrate 10, the guiding mask 40 and the target substrate 30 can be aligned with one another by relative movements of the three platforms. Alternatively, in another embodiment, the guiding mask can be disposed on the target surface or the transfer surface by any other mechanism, such as magnetic adhesion, electrostatic adhesion or negative pressure adhesion.

Besides, as shown in FIG. 3, in order to allow each guiding structure 41 to guide the corresponding electronic element 20 accurately for achieving a high transferring yield rate, in this embodiment, during alignment of the transfer substrate 10, the target subtract 30 and the guiding mask 40, the two platforms can not only move along a horizontal direction but also move close to each other, so that two sides of the guiding mask 40 can contact with the transfer substrate 10 and the target substrate 30 respectively after completion of the alignment of the transfer substrate 10, the target substrate 30 and the guiding mask 40. A thickness of the guiding mask 40 can be configured to be greater than a thickness of each electronic element 20, so as to prevent each electronic element 20 from contacting with the target substrate 30 when the guiding mask 40 contacts with the transfer substrate 10 and the target substrate 30. The aforementioned configuration reduces a transferring distance of each electronic element 20 to a difference between the thickness of the guiding mask 40 and the thickness of each electronic element 20 for preventing an accidental displacement or flipping of each electronic element 20 during the transferring process, so as to achieve the high transferring yield rate. Moreover, the aforementioned configuration also solves a problem in the prior art that the electronic element may be displaced, disoriented or flipped due to incomplete alignment or parallelism of the two platforms caused by low equipment accuracy and low equipment stability. However, the present invention is not limited to this embodiment. For example, in another embodiment, the guiding mask can be configured to be separated away from the transfer substrate and/or the target substrate when the transfer substrate, the target substrate and the guiding mask are aligned with one another.

Preferably, the difference between the thickness of the guiding mask 40 and the thickness of each electronic element 20 can be designed from 0.5 to 20 micrometers.

Furthermore, in this embodiment, there can be two coating layers, such as two fluoride coating layers, respectively disposed on the two sides of the guiding mask 40, so that the guiding mask 40 can be separated from the transfer substrate 10 and the target substrate 30 easily after completion of the transferring process, which facilitates reuse of the guiding mask 40.

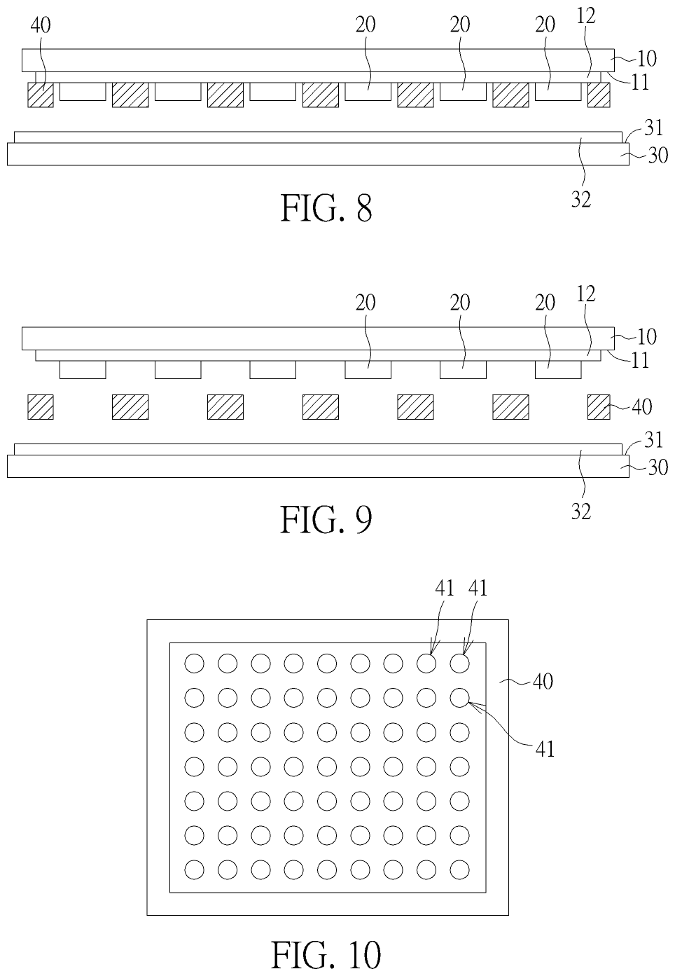

In addition, please refer to FIG. 3 and FIG. 10. FIG. 10 is a diagram of the guiding mask 40 according to the embodiment of the present invention. As shown in FIG. 3 and FIG. 10, in this embodiment, each guiding structure 41 of the guiding mask 40 can be a through hole which has a bore diameter greater than a width of the corresponding electronic element 20. Preferably, in order to allow each guiding structure 41 to guide the corresponding electronic element 20 accurately for achieving the high transferring yield rate, a difference between the bore diameter of each through hole and the width of the corresponding electronic element 20 can be designed from 2 to 10 micrometer, and a ratio of an open area of an end portion of each through hole adjacent to the transfer substrate 10 to an open area of another end portion of each through hole adjacent to the target substrate 30 can be designed from 0.9 to 1.1.

In step S4, the present invention can utilize a laser source 50 to disengage at least one of the plurality of electronic elements 20 corresponding to at least one predetermined area of the transfer substrate 10 from the adhesive layer 12 by applying at least one laser beam toward the at least one predetermined area to achieve releasing of the at least one of the plurality of electronic element 20. However, the present invention is not limited to this embodiment. For example, in another embodiment, when the electronic element is disposed on the transfer substrate by another mechanism, such as magnetic adhesion or electrostatic adhesion, the electronic element can be disengaged from the transfer substrate by a corresponding releasing mechanism, such as magnetic repulsion, electrostatic repulsion or ultrasonic technology.

Finally, as shown in FIG. 6 and FIG. 7, after completion of transferring of the released at least one electronic element 20, the target substrate 30, the transfer substrate 10 and/or the guiding mask 40 can be moved away from one another for facilitating follow-up work.

In contrast to the prior art, in the present invention, the released electronic element can be guided by the guiding structure of the guiding mask, so as to transfer the released electronic element to the target surface of the target substrate correctly and accurately. Therefore, the present invention does not necessarily require equipment with high accuracy and high stability. In other words, the present invention can achieve a high transferring yield rate even under a condition of low equipment accuracy and low equipment stability. Furthermore, the guiding mask of the present invention can be reused, which reduces manufacturing cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for transferring electronic elements comprising:
providing a transfer substrate comprising a transfer surface, and disposing a plurality of electronic elements on the transfer surface;
providing a target substrate comprising a target surface, and disposing the target substrate opposite to the transfer substrate, so that the transfer surface faces toward the target surface;
providing a guiding mask comprising at least one guiding structure, and disposing the guiding mask between the transfer substrate and the target substrate; and
releasing at least one of the plurality of electronic elements disposed on the transfer surface, and guiding the at least one of the plurality of electronic elements by the at least one guiding structure to transfer the at least one of the plurality of electronic elements to the target surface of the target substrate.

2. The method of claim 1, further comprising contacting two sides of the guiding mask with the transfer substrate and the target substrate respectively.

3. The method of claim 2, wherein a thickness of the guiding mask is greater than a thickness of each of the plurality of electronic elements, so that each of the plurality of electronic elements is prevented from contacting with the target substrate when the guiding mask contacts with the transfer substrate and the target substrate.

4. The method of claim 1, further comprising releasing the at least one of the plurality of electronic elements disposed on the transfer surface by applying at least one laser beam.

5. The method of claim 1, further comprising disposing an adhesive layer on the transfer surface, so as to dispose the plurality of electronic elements on the transfer surface by the adhesive layer.

6. The method of claim 1, further comprising disposing an adhesive layer on the target surface, so as to adhere the at least one released electronic element to the target surface by the adhesive layer.

7. The method of claim 1, wherein a bore diameter of the at least one guiding structure is greater than a width of a corresponding one of the plurality of electronic elements.
